(19) United States
(12) Patent Application Publication
(10) Pub. No.: US 2026/0321530 A1
(43) Pub. Date: Oct. 15, 2026

(54) THIN FILM SWITCH USING A SINGLE-LAYERED FLEXIBLE BODY AS A CARRIER

(71) Applicants: Logitech Europe S.A., Lausanne (CH); Logitech Technology (Suzhou) Company Limited, Suzhou New District (CN)

(72) Inventors: Houguang TANG, Xiamen City (FJ); Zhaozheng WANG, Xiamen City (FJ); Ming YANG, Xiamen City (CN)

(21) Appl. No.: 19/101,171

(22) PCT Filed: Mar. 20, 2024
(86) PCT No.: PCT/CN2024/082801

§ 371 Date: Feb. 4, 2025

(30) Foreign Application Priority Data
Sep. 13, 2023 (CN) 202322489628.X

(51) Int. Cl. H01H 13/704

(52) U.S. Cl. CPC H01H 13/704

(57) ABSTRACT

The disclosure discloses a thin film switch assembly using a single-layered flexible body as a carrier and pertains to the field of thin film switches. The technical solution includes a flexible body, one side of the flexible body is successively printed with a circuit layer and an insulating ink layer, the insulating ink layer comprises an isolation portion and a blank portion, only the isolation portion of the insulating ink layer covers the circuit layer, the flexible body is folded in half towards the side printed with the insulating ink layer, and after the flexible body is folded in half, the circuit layer located in the blank portion forms a conduction circuit. The disclosure adopts a single-layered flexible body folded in half to simplify the production and facilitate the development of thin film switches towards miniaturization and shape diversification.

### CROSS-REFERENCE TO RELATED APPLICATIONS

This application is a National Phase Application of PCT Application, serial Number PCT/CN2024/082801, filed Mar. 20, 2024 which claims the benefit of Chinese application serial number 202322489628.X filed Sep. 13, 2023. Both Applications are herein incorporated by reference.

### TECHNICAL FIELD

Embodiments of the disclosure provided herein relate to the field of thin film switches, particularly to a thin film switch using a single-layered flexible body as a carrier.

### BACKGROUND ART

The typical structure of a thin film switch is a three-layer structure, which consists of an upper flexible layer (including a circuit printed on the upper flexible layer), a middle isolation layer, and a lower flexible layer (including a circuit printed on the lower flexible layer). Conventionally, the middle isolation layer is a flexible film, the flexible film is cut into shape by the die cutting process, the cut flexible layer has a lateral width limit, conventionally not less than 1 mm, which limits the distance between the circuit conduction contacts of the upper and lower flexible layers of the thin film switch, which is not conducive to the development of products towards miniaturization and shape diversification.

### SUMMARY

To address the defects of the prior art, an objective of the present disclosure is to provide a thin film switch assembly using a single-layered flexible body as a carrier for the thin film switch elements. The advantage is that it replaces the thin film of the middle isolation layer with a printed ink layer to reduce the thickness of the middle isolation layer and make the size of the thin film switch assembly smaller. The design also adopts a single-layered flexible body folded in half to simplify the production of the thin film switch assembly and facilitate the development of thin film switches towards miniaturization and shape diversification. To achieve the foregoing objective, the present disclosure provides the following technical solutions.

Embodiments of the disclosure include a thin film switch assembly having a single-layered flexible body as a carrier, wherein the thin film switch assembly includes a flexible body. One side of the flexible body includes a circuit layer and an insulating ink layer that are printed thereon. The insulating ink layer includes an isolation portion and a blank portion, wherein only the isolation portion of the insulating ink layer covers the circuit layer when the flexible body is folded in half towards the side printed with the insulating ink layer. Moreover, after the flexible body is folded in half, the portion of the circuit layer located in the blank portion forms a conduction circuit.

The flexible body is also provided with a folding portion at the folding line to allow the flexible body to be easily folded. The folding portion may also include a plurality of through holes formed through the flexible body and in an array that extends along the folding line.

A connector is arranged at the edge of the flexible body, and the circuit layer and the insulating ink layer are extended to and disposed within the connector.

A portion of the blank portion of the insulating ink layer is located at an end of the connector, and the end of the connector forms a wiring port. The connector is located on a side of the flexible body that is separated by the folding line.

In some embodiments, the sides of the flexible body is bonded together and fixed with glue after being folded.

Compared with the prior art, the present disclosure has at least the following advantages. Through the use of a circuit layer and the insulating ink printed on the flexible body of the thin film switch assembly, the need for a middle isolation layer and a lower flexible body commonly used in conventional thin film switch designs are eliminated and all of the thin film functions of a three-layer structure can be realized. Also, the thin film of the middle isolation layer commonly used in conventional thin film switch designs is replaced with a printing ink layer, which reduces the thickness of the middle isolation layer and makes the size of the thin film switch assembly smaller. A single-layered flexible body design that is folded in half, which is disclosed herein, simplifies the production of the thin film switch assembly and facilitates the development of thin film switches towards miniaturization and shape diversification.

Another advantage of the thin film switch assembly design disclosed herein is that the array of holes that are formed along the folding line will tend to hollow out the middle part of the flexible body and thus facilitate precise and device-to-device repeatable folding of the flexible body during a manufacturing process.

Embodiments of the disclosure include a thin film switch assembly that comprises a flexible body comprising a first surface and a central region, wherein the central region includes a folding portion that divides the first surface into a first surface region and a second surface region, a circuit layer formed on the first surface, and an insulating ink layer formed over the first surface. The circuit layer comprises a conductive layer, and at least a first portion of the circuit layer is formed on the first surface region of the central region and at least a second portion of the circuit layer is formed on the second surface region of the central region. A first portion of the insulating ink layer is formed on the first portion and the second portion of the circuit layer, and a second portion of the insulating ink layer includes a plurality of blank portions, wherein a portion of the circuit layer is exposed within each blank portion, two or more blank portions of plurality of blank portions are disposed on the first surface region, and two or more blank portions of plurality of blank portions are disposed on the second surface region. Therefore, when the flexible body is folded along the folding portion so that each of the two or more blank portions on the first surface region are positioned over a corresponding blank portion of the two or more blank portions disposed on the second surface region.

Embodiments of the disclosure include a thin film switch assembly that comprises a flexible body comprising a first surface, a connection region, and a central region, wherein the central region includes a folding portion that divides the first surface into a first surface region and a second surface region, a circuit layer formed on the first surface, and an insulating ink layer formed over the first surface. The circuit layer comprises a conductive layer, at least a first portion of the circuit layer is formed on the first surface region of the central region and at least a second portion of the circuit layer is formed on the second surface region of the central region, a third portion of the circuit layer comprises a plurality of traces that are disposed on the connection region, at least one trace of the plurality of traces extends between the third portion and the first portion, and at least one trace of the plurality of traces extends between the third portion and the second portion. A first portion of the insulating ink layer is formed on the first portion and the second portion of the circuit layer, and a second portion of the insulating ink layer includes a plurality of blank portions, wherein a portion of the circuit layer is exposed within each blank portion, two or more blank portions of plurality of blank portions are disposed on the first surface region, and two or more blank portions of plurality of blank portions are disposed on the second surface region. Therefore, when the flexible body is folded along the folding portion so that each of the two or more blank portions on the first surface region are positioned over a corresponding blank portion of the two or more blank portions disposed on the second surface region.

The thin film switch assembly may further include two or more blank portions disposed in the first surface region that comprise a first plurality of blank portions, and two or more blank portions disposed in the second surface region that comprise a second plurality of blank portions. The flexible body may comprise a first plurality of body openings in the first surface region and a second plurality of body openings in the second surface region, wherein the first plurality of blank portions disposed in the first surface region are positioned in an array around each of the body openings of the first pluralities of body openings, and the second plurality of blank portions disposed in the second surface region are positioned in an array around each of the body openings of the second pluralities of body openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a schematic structural diagram of disassembled components of a key structure assembly according to one or more embodiments of the disclosure.

FIG. 2 is an exploded schematic view of portions of an unfolded detection module, according to an embodiment of the disclosure.

FIG. 3 is a schematic view of an unfolded detection module according to an embodiment of the disclosure.

FIG. 4 is a schematic view of the folded detection module, according to an embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is further described in detail by referring to the accompanying drawings.

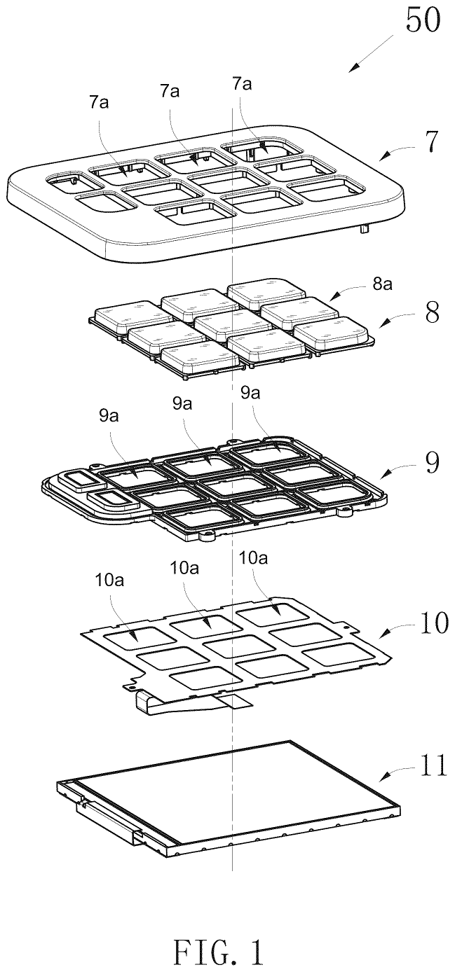

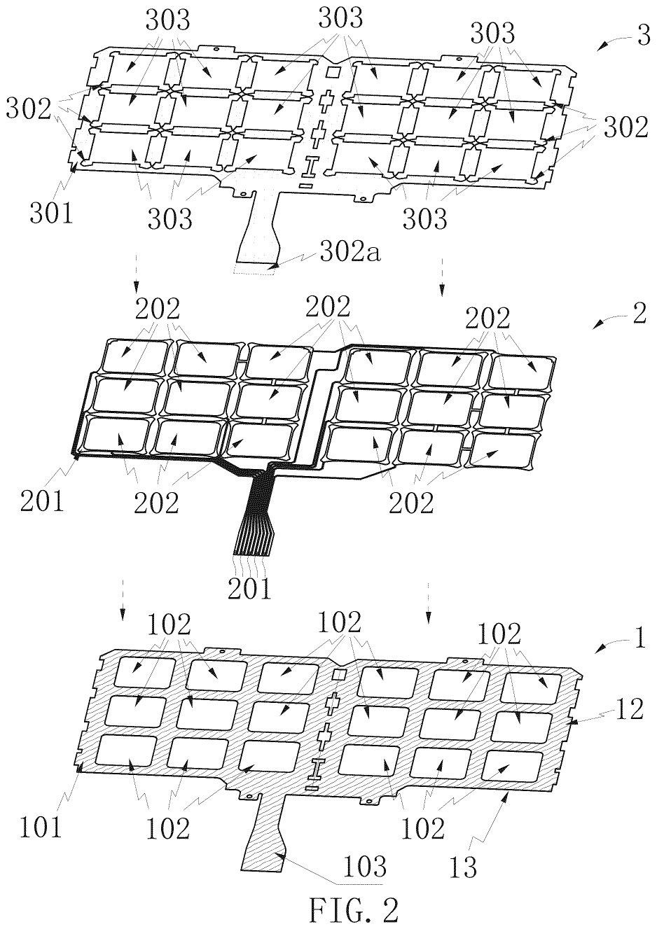

FIG. 1 illustrates an example of a key structure assembly 50 that includes a thin film switch assembly according to one or more embodiments of the disclosure provided herein. Embodiments of the key structure assembly 50 can include a top shell 7, keys 8, an elastic component 9, a detection module 10, and a display module 11. The detection module 10 includes one or more thin film switches, and for simplicity of discussion is often referred to herein as simply a thin film switch assembly 10. The top shell 7 has multiple holes 7a for the keys 8. The elastic component 9 is placed beneath the top shell 7. The elastic component 9 includes an elastomeric material layer that includes a plurality of openings 9a formed therein. The elastomeric material layer is configured to cause the keys 8 to bounce back when a user presses each of the keys 8. Below the elastic component 9 is the detection module 10, which comprises the thin film switch assembly 10, which is used to senses actions of the keys 8. As is discussed further below, thin film switch assembly 10 of the detection module includes a flexible body 1 that includes a single-layer thin film 101 and connection region 103. The single-layer thin film 101 (FIG. 2) includes a plurality of body openings 102 formed therein. When the single-layer thin film 101 is folded over itself the body openings 102 form the openings 10a in the detection module.

In some embodiments, a display module 11 is positioned beneath the thin film switch assembly 10. In some embodiments, the keys 8 include a key body 8a that is made of a translucent material, allowing images displayed by the display module 11 to be seen through the keys 8. In this case, users can directly see the bottommost display screen of the display module 11 through the translucent material of the key bodies 8a of the keys 8. Moreover, since all components between the key bodies 8a of the keys 8 and the display screen of the display module 11 are designed to be hollow (e.g., the elastic component and detection module include openings 9a and 10a, respectively), the visibility of the display screen is preserved without affecting the completeness of the displayed images. Additionally, since the display screen is placed at the bottommost layer, it will not be damaged due to prolonged use or unstable supports. In some embodiments, the display module 11 includes a TFT, LCD, OLED or Matrix LED module.

In some embodiments, the single-layer thin film 101 includes a plurality of body openings 102 (FIG. 2) that are surrounded by conductive contact structures 201 that are formed on the single-layer thin film 101. In one example, as shown in FIG. 2, the single-layer thin film 101 includes 18 conductive contact structures 201 formed on the single-layer thin film 101. The conductive contact structures 201 are used to form part of a plurality of thin film switches formed within the thin film switch assembly 10. The thin film switch assembly 10 includes a single-layer flexible body 1 that can function as a carrier, as shown in FIG. 2 to FIG. 4, wherein the thin film switch assembly 10 comprises a single-layered flexible body 1, one side of the flexible body 1 (e.g., top side 12) is successively printed with a circuit layer 2 and an insulating ink layer 3, the insulating ink layer 3 comprises an isolation portion 301 and a blank portion 302 and 302a, wherein only the isolation portion 301 of the insulating ink layer 3 covers the surface of the circuit layer 2, and the circuit layer 2 located under the blank portion 302 and 302a is exposed. The single-layer thin film 101 can comprise a polymeric film or sheet, such as a PET film. The circuit layer 2 includes a conductive layer (e.g., metal layer (Cu layer, Al layer, etc.)). The insulating ink layer 3 can include a dielectric layer. In some embodiments, the blank portions 302 are positioned in an array around the body openings 102 formed in the flexible body 1. In one embodiment, as shown in FIGS. 2-4, the blank portions 302 are positioned adjacent to and/or at each of the corners of each of the square or rectangular shaped body openings 102. In one example, as shown in FIG. 2, the isolation portion 301 includes 72 blank portions 302 (e.g., one in each corner of the rectangular openings 303). When the flexible body 1 is folded in half towards the side printed with the insulating ink layer 3, the circuit layer 2 and insulating ink layer 3 formed on either side of the folded halves will face each other and thin film switch can be formed. After the flexible body 1 is folded in half, the portion of the circuit layer 2 located in the blank portions 302, formed on either side of the fold, forms part of a switch so that a switch element is formed by the exposed portions of the conductive contact structures 201 of the circuit layer 2 positioned in the opposing blank portions 302, such that when a key 8 is pressed and urged against a portion of the flexible body 1, the exposed portions of the conductive contact structures 201 of the circuit layer 2 are placed in contact so that, for example, the formerly open switch is then closed.

The flexible body 1 may also comprise a first plurality of body openings 102 in a first surface region of side 12 and a second plurality of body openings in a second surface region of side 12, wherein a first plurality of blank portions 302 disposed in the first surface region are positioned in an array around each of the body openings 102 of the first pluralities of body openings, and the second plurality of blank portions 302 disposed in the second surface region are positioned in an array around each of the body openings 102 of the second pluralities of body openings. In some embodiments, the arrays of blank portions 302 around each of the body openings 102 can be symmetrical arrays of blank portions 302, such as an array that includes a blank portion 302 positioned at each corner of a square body opening 102.

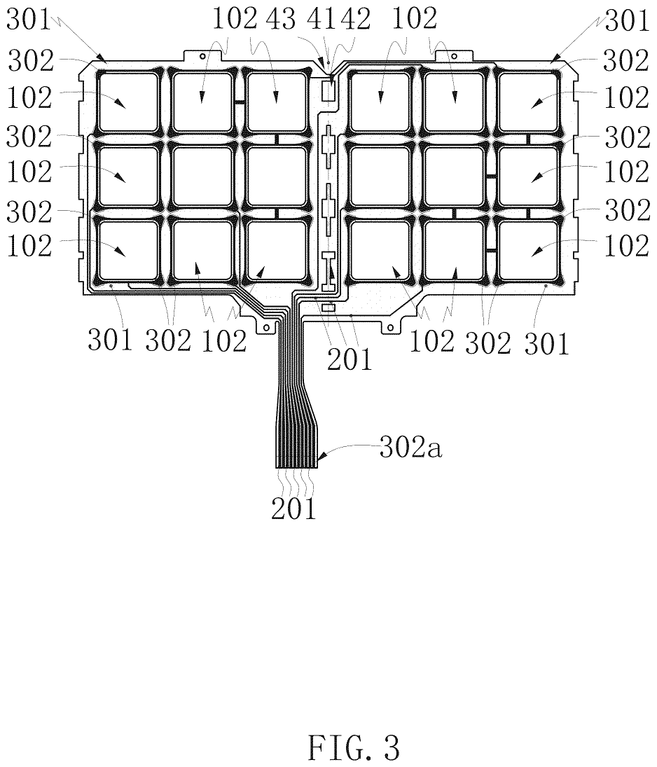

The flexible body 1 includes a central region 43 (FIG. 3) that is provided with a folding portion 4 that includes a folding line 41 for easy folding. The folding portion 4 of the central region 43 includes a plurality of through holes 42, which extend through the flexible body 1, and are positioned in an array along the folding line 41. The shape and cross-sectional area of the through holes 42 can be set according to a desired flexibility requirement. The through holes 42 can have different shapes in some embodiments and can have the same shape in other embodiments. The through holes 42, which are positioned in the middle part of the flexible body 1, will make the folding of the flexible body 1 easier and more accurate and/or precise.

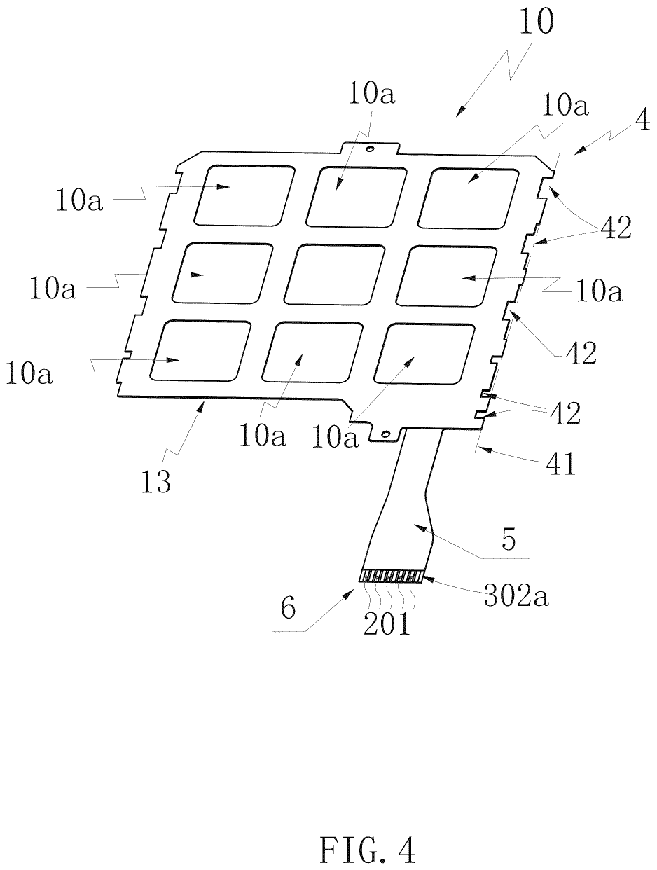

A connector 5 is arranged at the edge of the flexible body 1. The connector 5 and the flexible body 1 are formed integrally, wherein the flexible body 1 includes a connection region that extends outwards from a central body portion 13 (FIG. 4) of the flexible body 1. The circuit layer 2 and the insulating ink layer 3 extend from the central body portion 13 to the connector 5, and the connector 5 is located on a side of the folding line 41 (e.g., left side or right side of the folding line 41) so that the connector 5 will not interfere with portions of the flexible body 1 during the folding process.

A connector blank portion 302a of the insulating ink layer 3 is located at an end of the connector 5, and is formed so that the portion of the circuit layer 2 positioned at an end of the connector 5 is exposed, and forms a wiring port 6 to facilitate the connection between the circuit layer 2 and external power supply. At least one circuit disposed within the wiring port 6 is connected to a portion of the circuit layer 2 that is exposed in a blank portion 302 that is disposed on each side of the folding line 41. In other words, the portion of the circuit layer 2 positioned at an end of the connector 5 includes a plurality of conductive traces 201 that includes a first end that is positioned in the connector blank portion 302a of the connector 5 and a second end that is connected to a portion of the circuit layer 2 that is exposed within a blank portion 302 disposed on either side of the flexible body 1 in the central body portion 13. Each conductive trace 202 will typically be connected to a portion of the circuit layer 2 disposed within at least one of the blank portions 302 associated with each body opening 102. In this case, each conductive trace 201 is electrically connected at one end to a portion of the circuit layer 2 that forms an opposing part of a switch that is associated with a key 8 that is aligned with an opening 10a of the detection module 10, while an opposing end of each conductive trace 201 is exposed within the connector blank portion 302a of the connector 5.

During assembly of the thin film switch assembly 10 the flexible body 1 is coated with glue at one or more edges located on an edge of the insulating ink 3 to allow the sides of the flexible body 1 to be bonded together and fixed after folding. The glue can be pressure-sensitive adhesive.

A process of forming a thin film switch can be as follows. A circuit layer 2 is printed on the top side 12 of the flexible body 1. The circuit layer 2 positioned on either side of the fold line 41 can include electrically isolated portions, which include openings 202 that are positioned around the body openings 102 formed in the flexible body 1, such that each isolated portion is electrically isolated from adjacently positioned isolated portions by a physical gap.

Next, an insulating ink layer 3 is printed over the circuit layer 2 formed on the top side 12 of the flexible body 1. A first part of the insulating ink layer 3 covers the circuit layer 2 to form the isolation portion 301. A second part of the printed insulating ink layer 3 includes a blank portion 302 that is configured to expose regions of the circuit layer 2 that are used to form switch contact elements of the thin film switch assembly 10.

Next, the single-layered flexible body 1 is folded along a folding line 41 that is disposed in a central region 43 of the flexible body 1. During the process of folding the flexible body 1 about the folding line 41, the body openings 102 formed in the halves (i.e., first and second sides) of flexible body 1 are aligned to allow a through hole (i.e., opening 10a) to be formed through the folded flexible body 1.

Next, the folded halves of the flexible body 1 is bonded together by pressure-sensitive adhesive or other processes to form the thin film switch assembly 10.

In some embodiments, the thin switch assembly 10 can then be placed within a key structure assembly 50 to allow the detection of a pressing or release of a key 8 of the key structure assembly 50 by a user, due to the interaction of opposing portions of the conductive layer 2 positioned within a blank portion 302 of a switch within the formed thin film switch assembly 10. The detection of the actuation of a switch, by the pressing of a key 8, can be performed due to an electrical signal that is transmitted along one or more of the conductive traces 201 to the connector 5 when the switch is actuated (i.e., switch is opened or closed).

The above description is only a preferred embodiment of the present disclosure and not intended to limit the present disclosure. All modifications, equivalent replacements and improvements made within the design concept of the present disclosure shall be included in the scope of protection of the present disclosure.

1. A thin film switch assembly, comprising:
a flexible body comprising a first surface and a central region, wherein the central region includes a folding portion that divides the first surface into a first surface region and a second surface region;
a circuit layer formed on the first surface, wherein
the circuit layer comprises a conductive layer, and
at least a first portion of the circuit layer is formed on the first surface region of the central region and at least a second portion of the circuit layer is formed on the second surface region of the central region,
an insulating ink layer formed over the first surface, wherein
a first portion of the insulating ink layer is formed on the first portion and the second portion of the circuit layer, and
a second portion of the insulating ink layer includes a plurality of blank portions, wherein
a portion of the circuit layer is exposed within each blank portion,
two or more blank portions of plurality of the blank portions are disposed on the first surface region, and
two or more blank portions of plurality of blank portions are disposed on the second surface region; and
wherein the flexible body is folded along the folding portion so that each of the two or more blank portions on the first surface region are positioned over a corresponding blank portion of the two or more blank portions disposed on the second surface region.

2. The thin film switch assembly of claim 1, wherein the central region further comprises an array of through holes that are disposed within the folding portion and extend through the flexible body.

3. The thin film switch assembly of claim 2, wherein the array of through holes extend along a folding line disposed within the folding portion.

4. The thin film switch assembly of claim 1, wherein
the two or more blank portions disposed in the first surface region comprise a first plurality of blank portions,
the two or more blank portions disposed in the second surface region comprise a second plurality of blank portions,
the flexible body further comprises:
a first plurality of body openings in the first surface region; and
a second plurality of body openings in the second surface region,
the first plurality of blank portions disposed in the first surface region are positioned in an array around each of the body openings of the first pluralities of body openings, and
the second plurality of blank portions disposed in the second surface region are positioned in an array around each of the body openings of the second pluralities of body openings.

5. The thin film switch assembly of claim 1, wherein a portion of the first surface region and a portion of the second surface region are bonded together after being folded along the folding portion.

6. A thin film switch assembly, comprising:
a flexible body comprising a first surface, a connection region, and a central region, wherein the central region includes a folding portion that divides the first surface into a first surface region and a second surface region;
a circuit layer formed on the first surface, wherein
the circuit layer comprises a conductive layer,
at least a first portion of the circuit layer is formed on the first surface region of the central region and at least a second portion of the circuit layer is formed on the second surface region of the central region,
a third portion of the circuit layer comprises a plurality of traces that are disposed on the connection region,
at least one trace of the plurality of traces extends between the third portion and the first portion, and
at least one trace of the plurality of traces extends between the third portion and the second portion;
an insulating ink layer formed over the first surface, wherein
a first portion of the insulating ink layer is formed on the first portion and the second portion of the circuit layer, and
a second portion of the insulating ink layer includes a plurality of blank portions, wherein
a portion of the circuit layer is exposed within each blank portion,
two or more blank portions of plurality of blank portions are disposed on the first surface region, and
two or more blank portions of plurality of blank portions are disposed on the second surface region; and
wherein the flexible body is folded along the folding portion so that each of the two or more blank portions on the first surface region are positioned over a corresponding blank portion of the two or more blank portions disposed on the second surface region.

7. The thin film switch assembly of claim 6, wherein the central region further comprises an array of through holes that are disposed within the folding portion and extend through the flexible body.

8. The thin film switch assembly of claim 7, wherein the array of through holes extend along a folding line.

9. The thin film switch assembly of claim 6, wherein
the two or more blank portions disposed in the first surface region comprise a first plurality of blank portions,
the two or more blank portions disposed in the second surface region comprise a second plurality of blank portions,
the flexible body further comprises:
a first plurality of body openings in the first surface region; and
a second plurality of body openings in the second surface region,
the first plurality of blank portions disposed in the first surface region are positioned in an array around each of the body openings of the first pluralities of body openings, and
the second plurality of blank portions disposed in the second surface region are positioned in an array around each of the body openings of the second pluralities of body openings.

10. The thin film switch assembly of claim 6, wherein the insulating ink layer further comprises a connector blank portion, and at least a portion of the plurality of traces of the third portion are positioned in the connector blank portion.

11. The thin film switch assembly of claim 6, wherein the connection region further comprises a wiring port that comprises at least a portion of the plurality of traces of the third portion.

12. The thin film switch assembly of claim 6, wherein the connection region further comprises a connector that is positioned at the edge of the flexible body, and the circuit layer and the insulating ink layer extend from the first surface region and the second surface region to the connector.

13. A thin film switch assembly, comprising:
a flexible body comprising a first surface having a first surface region and a second surface region;
a circuit layer formed on the first surface, wherein
the circuit layer comprises a conductive layer, and
at least a first portion of the circuit layer is formed on the first surface region and at least a second portion of the circuit layer is formed on the second surface region,
an insulating layer formed over the first surface, wherein
a first portion of the insulating layer is formed on the first portion and the second portion of the circuit layer, and
a second portion of the insulating layer includes a plurality of blank portions, wherein
a portion of the circuit layer is exposed within each blank portion,
two or more blank portions of plurality of the blank portions are disposed on the first surface region, and
two or more blank portions of plurality of blank portions are disposed on the second surface region; and
wherein the flexible body is folded so that each of the two or more blank portions on the first surface region are positioned over a corresponding blank portion of the two or more blank portions disposed on the second surface region.

14. The thin film switch assembly of claim 13, wherein a folding portion is disposed between the first surface region and the second surface region.

15. The thin film switch assembly of claim 14, wherein the flexible body is folded along the folding portion.

16. The thin film switch assembly of claim 14, wherein an array of through holes are disposed within the folding portion and extend through the flexible body.

17. The thin film switch assembly of claim 16, wherein the array of through holes extend along a folding line disposed within the folding portion.

18. The thin film switch assembly of claim 13, wherein the insulating layer is an insulating ink layer.

19. The thin film switch assembly of claim 13, wherein
the two or more blank portions disposed in the first surface region comprise a first plurality of blank portions,
the two or more blank portions disposed in the second surface region comprise a second plurality of blank portions,
the flexible body further comprises:
a first plurality of body openings in the first surface region; and
a second plurality of body openings in the second surface region,
the first plurality of blank portions disposed in the first surface region are positioned in an array around each of the body openings of the first pluralities of body openings, and
the second plurality of blank portions disposed in the second surface region are positioned in an array around each of the body openings of the second pluralities of body openings.

20. The thin film switch assembly of claim 14, wherein a portion of the first surface region and a portion of the second surface region are bonded together after being folded along the folding portion.
